(19) United States
(12) Patent Application Publication
(10) Pub. No.: US 2026/0074684 A1
(43) Pub. Date: Mar. 12, 2026

(54) DELAY LOCKED LOOP CIRCUIT AND OPERATING METHOD

(71) Applicant: Winbond Electronics Corp., Taichung City (TW)

(72) Inventor: Chi-Hsiang Sun, Tainan (TW)

(73) Assignee: Winbond Electronics Corp., Taichung City (TW)

(21) Appl. No.: 18/991,700

(22) Filed: Dec. 23, 2024

(30) Foreign Application Priority Data
Sep. 12, 2024 (TW) 113134580

(51) Int. Cl. H03K 5/133; H03K 5/08; H03K 5/24

(52) U.S. Cl. CPC H03K 5/133; H03K 5/086; H03K 5/249

(57) ABSTRACT

Provided are a delay locked loop circuit and an operating method, for providing an output clock signal to a bidirectional data strobe (DQS). The delay locked loop circuit includes: a first delay line, configured to delay an input clock signal to generate the output clock signal; a second delay line, configured to receive the output clock signal and delay the output clock signal to generate a feedback clock signal; a phase comparator, configured to compare phases of the input clock signal and the feedback clock signal to adjust a delay of the first delay line; and a control circuit, controlling the second delay line, configured to adjust a delay of the second delay line to be aligned to a delay of an off-chip driver (OCD) coupled to the DQS.

### CROSS-REFERENCE TO RELATED APPLICATION

This application claims the priority benefit of Taiwan application serial no. 113134580, filed on Sep. 12, 2024. The entirety of the above-mentioned patent application is hereby incorporated by reference herein and made a part of this specification.

### BACKGROUND

### Technical Field

This disclosure relates to a circuit and a method, and in particular to a delay locked loop circuit and an operating method.

### Description of Related Art

In existing memory standards, the AC parameter (tDQSCK), is provided to the bidirectional data strobe (DQS) and is used to constrain the alignment between the data strobe and clock signals (CK). Consequently, the generation of precise tDQSCK has become a critical consideration in the field of memory technology.

### SUMMARY

The disclosure provides a delay locked loop circuit and an operating method, capable of generating an accurate output clock signal.

The delay locked loop circuit of the disclosure is configured to provide an output clock signal to a bidirectional data strobe. The delay locked loop circuit includes: a first delay line, configured to delay an input clock signal to generate the output clock signal; a second delay line configured to receive the output clock signal and delay the output clock signal by a first delay length to generate a feedback clock signal; a phase comparator, configured to compare phases of the input clock signal and the feedback clock signal to generate a first comparison result signal; and a control circuit, controlling the second delay line, configured to adjust a delay of the second delay line to be aligned to a delay of an off-chip driver coupled to the bidirectional data strobe.

The operating method of the disclosure is applied to a delay locked loop (DLL) circuit providing an output clock signal to a bidirectional data strobe (DQS). The operating method includes the following. An input clock signal is delayed by a first delay line of the delay locked loop circuit to generate the output clock signal. The output clock signal is received by a second delay line of the delay locked loop circuit, and the output clock signal is delayed by a first delay length to generate a feedback clock signal. Phases of the input clock signal and the feedback clock signal are compared by a phase comparator of the delay locked loop circuit to generate a first comparison result signal. A first delay adjustment signal is generated by a first control circuit of the delay locked loop circuit according to the first comparison result signal to adjust a delay of the first delay line. A second delay adjustment signal is generated to the second delay line by a second control circuit of the delay locked loop circuit, so that the first delay length generated by the second delay line is aligned with a second delay length of an off-chip driver on the bidirectional data strobe.

The delay locked loop circuit and the operating method of the disclosure can use the second delay line to simulate the delay of the off-chip driver, thereby effectively avoiding the direct use of a replica driver that copies the off-chip driver on a feedback path of the delay locked loop circuit, and thus effectively reduce the power consumption caused by the delay locked loop circuit and the operating method.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1 is a circuit block diagram of a delay locked loop circuit according to an embodiment of the disclosure.

FIG. 2A is a circuit block diagram of a second control circuit according to an embodiment of the disclosure.

FIG. 2B illustrates a truth table depicting the corresponding relationship between second comparison result signals and a second delay adjustment signal according to an embodiment of the disclosure.

FIG. 3 is a schematic diagram of operation waveforms of a second control circuit according to an embodiment of the disclosure.

FIG. 4 is a circuit diagram of a second delay line and a feedback selection circuit according to an embodiment of the disclosure.

FIG. 5A is a flow chart of an operating method of the disclosure.

FIG. 5B is a detailed flow chart of a step in FIG. 5A.

### DESCRIPTION OF THE EMBODIMENTS

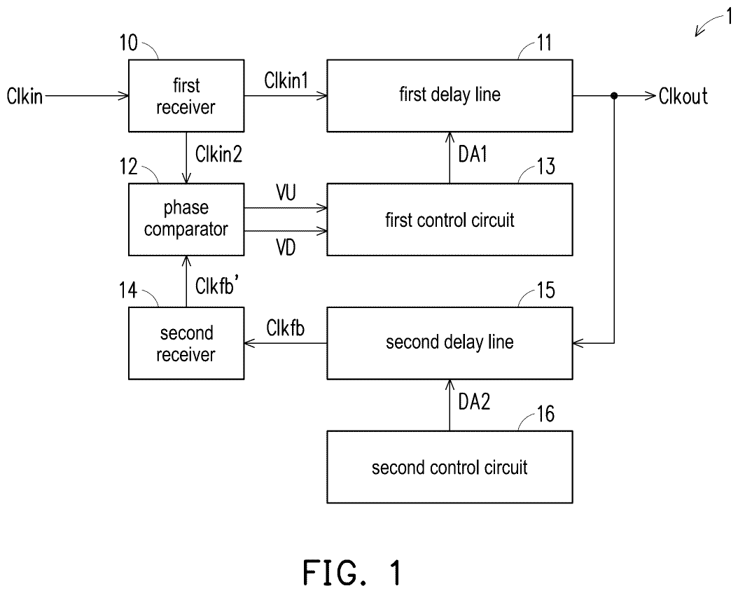

FIG. 1 is a circuit block diagram of a delay locked loop circuit according to an embodiment of the disclosure. A delay locked loop circuit 1 can be applied in a memory to provide an output clock signal to a bidirectional data strobe. Roughly speaking, the delay locked loop circuit 1 includes a first receiver 10, a first delay line 11, a phase comparator 12, a first control circuit 13, a second receiver 14, a second delay line 15, and a second control circuit 16. The delay locked loop circuit 1 can be used to receive an input clock signal Clkin to generate thane output clock signal Clkout, which is used as a clock signal tDQSCK in a memory system and meets the relevant standards of DDR3.

The delay locked loop circuit 1 can adjust and lock the delay between the input clock signal Clkin and the output clock signal Clkout through feedback. As the delay locked loop circuit 1 provides the output clock signal Clkout to the bidirectional data strobe, in order to incorporate the delay of an off-chip driver coupled to the bidirectional data strobe into consideration, and to ensure that the interval between the input clock signal Clkin and the output signal of the off-line driver complies with relevant standards, the second delay line 15 in the delay locked loop circuit 1 is controlled by the second control circuit 16, so that a first delay length generated by the second delay line 15 can be adjusted to be identical or approximate to a second delay length of the off-chip driver. Consequently, the phase comparator 12 compares a clock signal Clkin2 generated from the input clock signal Clkin with a clock signal Clkfb′ generated from the feedback clock signal Clkfb. Subsequently, through the joint operation of the phase comparator 12 and the first control circuit 13, the delay generated by the first delay line 11 is adjusted, thereby locking the delay between the input clock signal Clkin and the output clock signal Clkout within a predetermined delay range. Further, after the delay locked loop circuit 1 completes locking the output clock signal Clkout, the second control circuit 16 can be turned off to further save the power consumption of the delay locked loop circuit 1.

The first receiver 10 can receive the input clock signal Clkin and generate clock signals Clkin1 and Clkin2 and provide them to the first delay line 11 and the phase comparator 12 respectively. The input clock signal Clkin and the clock signals Clkin1 and Clkin2 may have the same phase or a phase difference with a preset delay. For example, the first receiver 10 may be composed of a buffer or other suitable circuits to provide the clock signals Clkin1 and Clkin2 with preset delays. For example, the first delay line 11 has multiple delay units connected in series, and can adjust the delay of the output clock signal Clkout it outputs according to a first delay adjustment signal DA1, i.e., the time difference between the input clock signal Clkin and the output clock signal Clkout.

Further, the output clock signal Clkout is provided to the second delay line 15. The second delay line 15 is controlled by the second control circuit 16, so that the second delay line 15 generates the same or similar delay as the off-chip driver. Then, the input clock signal Clkin and a feedback clock signal Clkfb are output as clock signals Clkin2 and Clkfb by the first receiver 10 and the second receiver 14 respectively, and are provided to the phase comparator 12. The phase comparator 12 compares the phase or delay of the clock signals Clkin2 and Clkfb to generate a first comparison result signal including an up-signal VU and a down-signal VD, and then controls the first control circuit 13 to generate the first delay adjustment signal DA1 to the first delay line 11 to adjust the delay of the output clock signal Clkout accordingly. Since the second delay line 15 is controlled by the second control circuit 15 and has the same or similar delay as the off-chip driver, the adjustment of the output clock signal Clkout can incorporate the delay of the off-chip driver into consideration, thereby complying with the relevant memory standards. In addition, after completing locking the output clock signal Clkout, the second control circuit 16 can be turned off to further save the power consumption of the delay locked loop circuit 1.

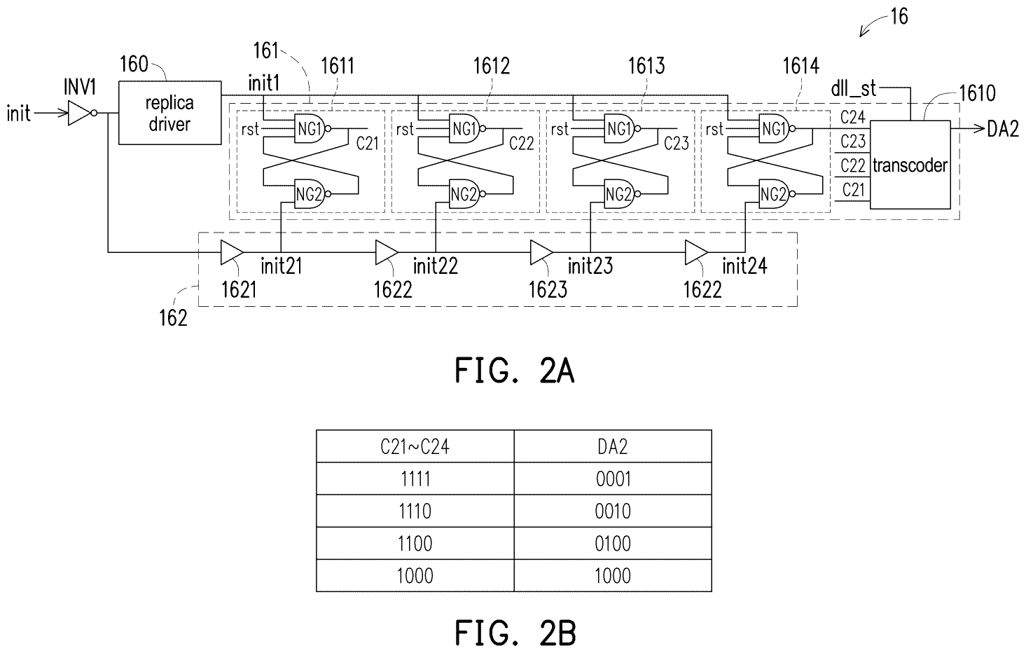

FIG. 2A is a circuit block diagram of a second control circuit 16 according to an embodiment of the disclosure. The second control circuit 16 includes an inverter INV1, a replica driver 160, a third delay line 162, and a detection circuit 161. The replica driver 160 can copy the circuit structure of the off-chip driver, so a replica drive signal init1 generated by the replica driver 160 has the same or similar delay as that of the off-chip driver. The third delay line 162 has multiple third delay line units 1621 to 1624 connected in series, and the third delay line 162 receives the same input signal as the replica driver 160, so that the third delay line units 1621 to 1624 are used to generate third delay line output signals init21 to init24 having different delay lengths. The detection circuit 161 is coupled to the replica driver 160 and the third delay line 162, and is used to compare the replica drive signal init1 generated by the replica driver 160 with the third delay line output signals init21 to init24 generated by the third delay line 162 to select a selected third delay line unit from the third delay line units 1621 to 1624 and generate a second delay adjustment signal DA2 according to the selected third delay line unit. In the above description, although the second delay line 15 is provided with four second delay line units 161 to 164 connected in series, those with ordinary knowledge in the art can certainly make changes according to different applications, and therefore, a different number of second delay line units are also within the scope of the variant embodiments.

The replica driver 160 has the same delay as the off-chip driver, so the detection circuit 161 can determine a selected third delay line unit by comparing the replica drive signal init1 with the third delay line output signals init21 to init24, and the third delay line output signal line output by the selected third delay line unit has a delay or phase close to that of the replica drive signal init1. In other words, the comparison process of the detection circuit 161 can be regarded as determining the number of third delay line units whose delay can simulate or substitute the delay generated by the replica driver 160. Therefore, after determining the selected third delay line unit in the third delay line 162, the second control circuit 16 can generate the corresponding second delay adjustment signal DA2 accordingly to provide the identifier of the selected third delay line unit to the second delay line 15. Furthermore, the second delay line 15 and the third delay line 162 may have the same circuit structure, that is, the second delay line 15 will also be formed by multiple second delay line units connected in series, and the circuit structure of each second delay line unit will be equivalent to that of each third delay line unit 1621 to 1624. In this way, the second delay line 15 can select an equivalent number of second delay line units according to the second delay adjustment signal DA2 to generate the feedback clock signal Clkfb, wherein the feedback clock signal possesses a delay identical or approximate to that of the off-line driver.

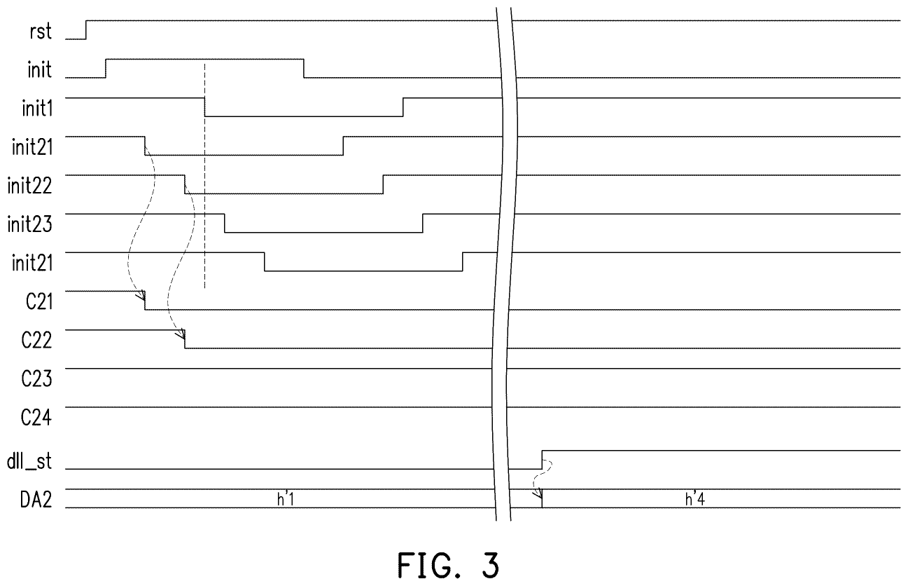

FIG. 3 is a schematic diagram of operation waveforms of a second control circuit 16 according to an embodiment of the disclosure. Next, please refer to FIG. 2A and FIG. 3 together with the following explanatory paragraphs to understand the operation process of the second control circuit 16 generating the second delay adjustment signal DA2.

When the second control circuit 16 receives a restart signal rst that switches from a low voltage level to a high voltage level, it means that the delay locked loop circuit 1 is started or restarted, and therefore the second controller 16 is turned on or energized accordingly to operate to set the delay generated by second delay line 15. Following the startup or restart of the phase locked loop circuit 1, the startup pulse signal init is provided to the second control circuit 16, and through the drive of the inverter INV1, the replica driver 160 and the third delay line 162 can generate the replica drive signal init1 and the third delay line output signals init21 to init24, respectively. The detection circuit 161 compares the replica drive signal init1 with the third delay line output signals init21 to init24, and selects the one that is closest to the replica drive signal init1 from the third delay line output signals init21 to init24 as the selected third delay line output signal. Selecting the closest one to the replica drive signal init1 means that the closest one of the third delay line output signals init21 to init24 that are ahead or behind the replica drive signal init1 can be selected as the selected third delay line output signal. Moreover, the third delay line unit that generates the selected third delay line output signal can also be selected as the selected third delay line unit. Accordingly, the detection circuit 161 may generate second comparison result signals C21 to C24 according to the comparison process, and convert them into the second delay adjustment signals DA2 by a decoder 1610, and finally provide them to the second delay line 15 according to the drive of a lock loop circuit start signal dll_st.

Specifically, the detection circuit 161 includes multiple comparison circuits 1611 to 1614, which are respectively coupled to the replica driver 160 and the corresponding third delay line units 1621 to 1624, for respectively comparing the replica drive signal init1 with the corresponding third delay line output signals init21 to init24 to generate multiple second comparison result signals C21 to C24. Each comparison circuit 1611 to 1614 can be a latch circuit, which includes a first NAND gate NG1 and a second NAND gate NG2. A first input end of the first NAND gate NG1 is coupled to an output end of the replica driver 160, a second input end of the first NAND gate NG1 is coupled to an output end of the second NAND gate NG2, and an output end of the first NAND gate NG1 generates a comparison signal. In addition, a first input end of the second NAND gate NG2 is coupled to the output end of the first NAND gate NG1, and a second input end of the second NAND gate NG2 is coupled to the output end of the corresponding third delay line unit.

FIG. 2B illustrates a truth table depicting the corresponding relationship between second comparison result signals C21 to C24 and a second delay adjustment signal DA2 according to an embodiment of the disclosure. The second comparison result signals C21 to C24 generated by the detection circuit 161 have the data type of thermometer code. The second comparison result signals C21 to C24 respectively represent the phase relationship between the third delay line output signals init21 to init24 and the replica drive signal init1 for each stage, with the value of 1 representing the lead and the value of 0 representing the lag. Therefore, the values 1111 to 1000 of the second comparison result signals C21 to C24 respectively represent different phase relationships. In the embodiment of FIG. 3, since the negative edge of the replica drive signal init1 falls between the third delay line output signals init22 and init23, the second comparison result signals C21 to C24 generated by the comparison circuits 1611 to 1614 have a value of 1100. Further, the decoder 1610 can convert the second comparison result signals C21 to C24 of the thermometer code into the second delay adjustment signal DA2 of one-hot encoding. The decoder 1610 receives the second comparison result signals C21 to C24 with a value of 1100, converts them into the second delay adjustment signal DA2 with a value of 0100, and provides the second delay adjustment signal DA2 to the second delay line 15 driven by the lock loop circuit start signal dll_st.

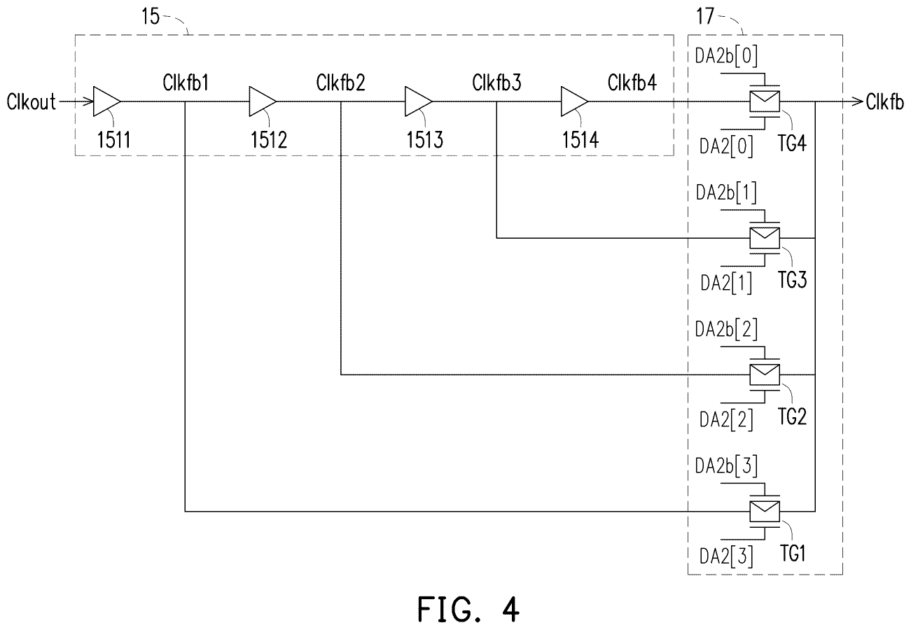

FIG. 4 is a circuit diagram of a second delay line 15 and a feedback selection circuit 17 according to an embodiment of the disclosure. The second delay line 15 includes multiple second delay line units 1511 to 1514 connected in series to form a series. More specifically, the second delay line 15 has the same circuit structure as the third delay line 162, and each second delay line unit 1511 to 1514 is the same as the third delay line unit 1621 to 1624, and thus has the same or similar delay. The feedback selection circuit 17 has multiple switch circuits TG1 to TG4, which are respectively coupled to output ends of the second delay line units 1511 to 1514, and selectively output one of the second delay line output signals Clkfb1 to Clkfb4 as the feedback clock signal Clkfb according to each bit of the second delay adjustment signal DA2. For example, the switch circuits TG1 to TG4 may be transmission gates, which are controlled by the corresponding bits of the second delay adjustment signal DA2 and a reverse second delay adjustment signal DA2b.

After the second control circuit 16 determines the number of the second delay line units to be used to simulate the subsequent delay of the replica driver, the second control circuit 16 can generate the second delay adjustment signal DA2 carrying the quantity information. The second delay adjustment signal DA2 can be provided to the feedback selection circuit 17, so that the feedback selection circuit 17 selects the selected second delay line output signal from the second delay line output signals Clkfb1 to Clkfb4 and outputs the selected second delay line output signal as the feedback clock signal Clkfb.

In the embodiment of FIG. 3, when the feedback selection circuit 17 receives the second delay adjustment signal DA2 with a value of 0100, affected by the bit [2] of the second delay adjustment signal DA2 with a value of 1, the switch circuit TG2 is turned on, so that the second delay line output signal Clkfb2 is selected as the selected second delay line output signal, and output as the feedback clock signal Clkfb. In this way, the second delay line 15 can select the feedback clock signal Clkfb under the selection of the feedback selection circuit 17, which has the same or similar delay as the off-chip driver.

Finally, after the delay locked loop circuit 1 completes locking, the second control circuit 16 can be turned off accordingly. In contrast to setting the replica driver directly on the feedback path of the delay locked loop circuit 1, the delay locked loop circuit 1 chooses to set a series of second delay line units on the feedback path and achieves the same or similar delay as the off-chip driver by using an appropriately selected number of series of the second delay line units in the second delay line 15. In this way, by appropriately selecting the implementation method of the second delay line unit (e.g., by forming it with an inverter), it is possible to achieve the same effect with lower power consumption than that of the replica driver, and to turn off the second control circuit 16 after the output clock signal Clkout locks in place, thus effectively reducing the power consumption of the delay locked loop circuit 1.

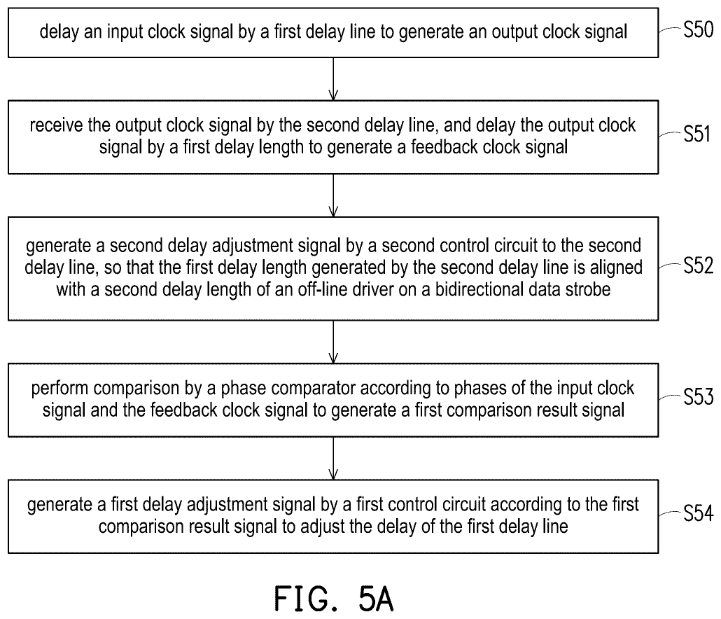

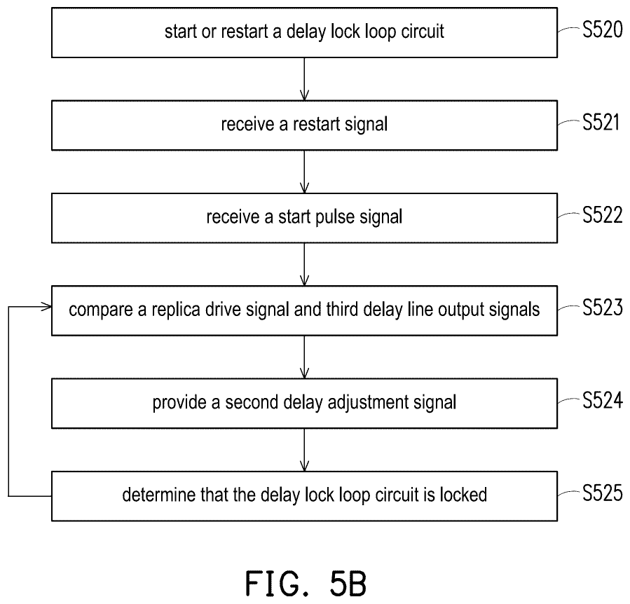

FIG. 5A is a flow chart of an operating method of the disclosure. The operating method illustrated in FIG. 5A can be applied to the delay locked loop circuit 1 of FIG. 1 and has steps S50 to S54. In step S50, the input clock signal Clkin can be delayed by the first delay line 11 to generate the output clock signal Clkout. In step S51, the output clock signal Clkout can be received by the second delay line 15, and the output clock signal Clkout is delayed by a first delay length to generate the feedback clock signal Clkfb. In step S52, the second delay adjustment signal DA2 can be generated by the second control circuit 16 to the second delay line 15, so that the first delay length generated by the second delay line 15 is aligned with a second delay length of the off-chip driver coupled to the bidirectional data strobe. In step S53, the phase comparator 12 can perform comparison according to the phases of the input clock signal Clkin and the feedback clock signal Clkfb to generate a first comparison result signal. In step S54, the first delay adjustment signal DA1 can be generated by the first control circuit 13 according to the first comparison result signal to adjust the delay of the first delay line 11. Specifically, since the delay locked loop circuit 1 has a loop circuit type, the above flowchart does not limit the execution order of each step, which may be executed simultaneously or according to a preset order. For details of each step, please refer to the description of the delay locked loop circuit 1 in the paragraph above and therefore are not be repeated in the following.

FIG. 5B is a detailed flow chart of a step in FIG. 5A. The detailed flow chart shown in FIG. 5B can be executed by the second control circuit 16 in FIG. 1 and has steps S520 to S525. In step S520, the delay locked loop circuit 1 is first started or restarted. In step S521, the second control circuit 16 can receive the restart signal rst, thereby energized each comparison circuit 1611 to 1614. In step S522, the second control circuit 16 can receive the start pulse signal init, so that the replica driver 160 and the third delay line 162 generate the replica drive signal init1 and the third delay line output signals init21 to init24 respectively. In step S523, the detection circuit 161 may compare the phases of the replica drive signal init1 and the third delay line output signals init21 to init24 to find the closest selected third delay line output signal. In step S524, according to the driving of the lock loop circuit start signal dll_st, the detection circuit 161 can output the second delay adjustment signal DA2 to the second delay line 15, so that the second delay line 15 generates the same or similar delay as the off-chip driver. In step S525, when it is determined that the delay locked loop circuit 1 is locked, the second control circuit 16 may be correspondingly turned off or controlled to a standby state to reduce power consumption until the next time a restart signal rst is received, and then the loops of steps S521 to S525 are re-executed to set the delay of the second delay line 15.

To sum up, the delay locked loop circuit and the operating method of the disclosure can be utilized to achieve the same or similar delay as an off-chip driver by setting adjustable second delay line units in series on the feedback path and by appropriately selecting the number of second delay line units to be connected in series in the second delay line. In this way, by appropriately selecting the implementation method of the second delay line units, it is possible to achieve the same effect with lower power consumption than that of the replica driver, and to turn off the second control circuit after the output clock signal locks in place, thus effectively reducing the power consumption of the delay locked loop circuit.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A delay locked loop circuit, configured to provide an output clock signal to a bidirectional data strobe, the delay locked loop circuit comprising:
a first delay line, configured to delay an input clock signal to generate the output clock signal;
a second delay line, configured to receive the output clock signal and delay the output clock signal by a first delay length to generate a feedback clock signal;
a phase comparator, configured to compare phases of the input clock signal and the feedback clock signal to generate a first comparison result signal;
a first control circuit, configured to generate a first delay adjustment signal according to the first comparison result signal to adjust a delay of the first delay line; and
a second control circuit, configured to generate a second delay adjustment signal to the second delay line, such that the first delay length generated by the second delay line is aligned with a second delay length of an off-chip driver coupled to the bidirectional data strobe.

2. The delay locked loop circuit according to claim 1, wherein the second control circuit is turned on when the delay locked loop circuit is started or restarted, and is turned off after the output clock signal is locked.

3. The delay locked loop circuit according to claim 1, wherein the second delay line comprises a plurality of second delay line units connected in series to generate a plurality of second delay line output signals having different delays, the second control circuit selects a selected second delay line unit from the second delay line units by the second delay adjustment signal to select a selected second delay line output signal generated by the selected second delay line unit as the feedback clock signal.

4. The delay locked loop circuit according to claim 3, wherein the second control circuit comprises:
a replica driver, configured to generate a replica drive signal having a same delay as the off-chip driver;
a third delay line, having a plurality of third delay line units connected in series, wherein the third delay line units respectively generate a plurality of third delay line output signals having different delay lengths; and
a detection circuit, configured to compare the replica drive signal and the third delay line output signals to select a selected third delay line unit from the third delay line units, and to generate the second delay adjustment signal according to the selected third delay line unit.

5. The delay locked loop circuit according to claim 4, wherein when the delay locked loop circuit is started, a start pulse signal is provided to the replica driver to generate the replica drive signal, the start pulse signal is provided to the third delay line, such that the third delay line units of the third delay line generate the third delay line output signals respectively, and the detection circuit compares the replica drive signal and the third delay line output signals to select the selected third delay line unit having a delay close to the replica drive signal from the third delay line units.

6. The delay locked loop circuit according to claim 4, wherein the second delay line has a same circuit structure as the third delay line, and each of the second delay line units and each of the third delay line units also have a same circuit structure.

7. The delay locked loop circuit according to claim 5, wherein the detection circuit comprises:
a plurality of comparison circuits, respectively coupled to the replica driver and the corresponding third delay line unit, configured to respectively compare a replica driver signal and the corresponding third delay line output signal to generate a plurality of second comparison result signals.

8. The delay locked loop circuit according to claim 6, wherein each of comparison circuits is a latch circuit comprising a first NAND gate and a second NAND gate, wherein
a first input end of the first NAND gate is coupled to an output end of the replica driver, a second input end of the first NAND gate is coupled to an output end of the second NAND gate, and an output end of the first NAND gate generates a comparison signal, and
a first input end of the second NAND gate is coupled to the output end of the first NAND gate, and a second input end of the second NAND gate is coupled to the output end of the corresponding third delay line unit.

9. The delay locked loop circuit according to claim 7, wherein the plurality of second comparison result signals are thermometer codes, the second delay adjustment signal is a one-hot encoding signal, the second control circuit further comprises a decoder, coupled to the plurality of comparison circuits, the decoder is configured to convert the plurality of second comparison result signals into the second delay adjustment signal.

10. The delay locked loop circuit according to claim 3 further comprising:
a feedback selection circuit, comprising a plurality of switch circuits, respectively coupled to output ends of the second delay line units, wherein the switch circuits are respectively controlled by a plurality of bits of the second delay adjustment signal, the feedback selection circuit selects the selected second delay line unit according to the bits of the second delay adjustment signal, and provides the selected second delay line output signal generated by the selected second delay line unit to the phase comparator as the feedback clock signal.

11. An operating method, applied to a delay locked loop circuit providing an output clock signal to a bidirectional data strobe, the operating method comprising:
delaying an input clock signal by a first delay line of the delay locked loop circuit to generate the output clock signal;
receiving the output clock signal by a second delay line of the delay locked loop circuit, and delaying the output clock signal by a first delay length to generate a feedback clock signal;
comparing according to phases of the input clock signal and the feedback clock signal by a phase comparator of the delay locked loop circuit to generate a first comparison result signal;
generating a first delay adjustment signal by a first control circuit of the delay locked loop circuit according to the first comparison result signal to adjust a delay of the first delay line; and
generating a second delay adjustment signal to the second delay line by a second control circuit of the delay locked loop circuit, such that the first delay length generated by the second delay line is aligned with a second delay length of an off-chip driver coupled to the bidirectional data strobe.

12. The operating method according to claim 11, further comprising turning on the second control circuit when the delay locked loop circuit is started or restarted, and turning off the second control circuit after the output clock signal is locked.

13. The operating method according to claim 11, further comprising generating a plurality of second delay line output signals having different delays respectively by a plurality of second delay line units connected in series in the second delay line, and selecting a selected second delay line unit from the second delay line units according to the second delay adjustment signal, and taking a selected second delay line output signal generated by the selected second delay line unit as the feedback clock signal.

14. The operating method according to claim 13, comprising:
generating, by a replica driver of the second control circuit, a replica drive signal having a same delay as the off-chip driver;
generating, by a third delay line of the second control circuit, a plurality of third delay line output signals having different delay lengths, wherein the third delay line has a plurality of units coupled in series, to respectively generate the plurality of third delay line output signals; and
comparing, a detection circuit of the second control circuit, the replica drive signal and the plurality of third delay line output signals to select a selected third delay line unit from the plurality of third delay line units, and generate the second delay adjustment signal according to the selected third delay line unit.

15. The operating method according to claim 14, further comprising:
when the delay locked loop circuit is started, providing a start pulse signal to the replica driver to generate the replica drive signa, and providing the start pulse signal to the third delay line, such that the third delay line units of the third delay line generate the third delay line output signals respectively; and
comparing, by the detection circuit, the replica drive signal and the third delay line output signals, to select the selected third delay line unit having a delay close to the replica drive signal from the third delay line units.

16. The operating method according to claim 14, wherein the second delay line has a same circuit structure as the third delay line, and each of the second delay line units and each of the third delay line units also have a same circuit structure, the operating method further comprises:
selecting the selected second delay line unit from the second delay line according to the selected third delay line unit, such that the second delay line and the third delay line generate delays having a same length.

17. The operating method according to claim 15, further comprising:
comparing, respectively by a plurality of comparison circuits of the detection circuit, a replica driver signal and the corresponding third delay line output signal, to generate a plurality of second comparison result signals.

18. The operating method according to claim 17, wherein the plurality of second comparison result signals are thermometer codes, the second delay adjustment signal is a one-hot encoding code, the operating method further includes converting, by a decoder of the second control circuit, the plurality of second comparison result signals into the second delay adjustment signal.

19. The operating method according to claim 13, wherein the delay locked loop circuit further comprises a feedback selection circuit, comprising a plurality of switch circuits, respectively coupled to output ends of the second delay line units, the operating method further comprises:
controlling the plurality of switch circuits respectively according to a plurality of bits of the second delay adjustment signal, such that the feedback selection circuit selects the selected second delay line unit according to the plurality of bits of the second delay adjustment signal, and provides the selected second delay line output signal generated by the selected second delay line unit to the phase comparator as the feedback clock signal.
